(19) United States
(12) Patent Application Publication
(10) Pub. No.: US 2025/0048728 A1
(43) Pub. Date: Feb. 6, 2025

(54) SEMICONDUCTOR STRUCTURE AND METHOD OF FORMING THE SAME

(71) Applicants: Semiconductor Manufacturing International (Shanghai) Corporation, Shanghai (CN); Semiconductor Manufacturing International (Beijing) Corporation, Beijing (CN)

(72) Inventor: Fei ZHOU, Shanghai (CN)

(21) Appl. No.: 18/714,808

(22) PCT Filed: Dec. 24, 2021
(86) PCT No.: PCT/CN2021/141115

§ 371 Date: May 30, 2024

(51) Int. Cl. H01L 27/092; H01L 21/822; H01L 21/8238; H01L 29/06; H01L 29/417; H01L 29/423; H01L 29/66; H01L 29/775; H01L 29/786

(52) U.S. Cl. CPC H01L 27/0922; H01L 21/8221; H01L 21/823814; H01L 21/823871; H01L 21/823878; H01L 29/0673; H01L 29/41733; H01L 29/42392; H01L 29/66439; H01L 29/66545; H01L 29/775; H01L 29/78696

(57) ABSTRACT

A semiconductor structure includes a substrate and a vertical stack structure over the substrate. The vertical stack structure includes a channel region and a source/drain region on two sides of the channel region. The channel region includes a first stack region, an isolation region, and a second stack region. The structure also includes a first doped source/drain region, a first contact layer located on a surface of the first doped source/drain region, a second doped source/drain region located over the first contact layer, and a second contact layer located on a surface of the second doped source/drain region. The structure also includes a second connection layer electrically connected to the second doped source/drain region through the second contact layer, and a first connection layer electrically connected to the first doped source/drain region through the first contact layer.

### CROSS-REFERENCE TO RELATED APPLICATIONS

This application is a national phase entry under 35 U.S.C § 371 of International Application No. PCT/CN2021/141115, filed on Dec. 24, 2021, the entire content of which is incorporated herein by reference.

### TECHNICAL FIELD

The present disclosure generally relates to the field of semiconductor manufacturing technology and, more particularly, relates to a semiconductor structure and a method of forming the same.

### BACKGROUND

With development of semiconductor technology, the capability of a conventional planar metal-oxide semiconductor field-effect transistor to control channel current may become weaker, resulting in serious leakage current. A fin field effect transistor (Fin FET) is an emerging multi-gate device. A Fin FET generally includes a fin protruding from a surface of a semiconductor substrate, a gate structure covering part of a top surface and a sidewall of the fin, and a doped source/drain region in the fin on two sides of the gate structure. Compared with a planar metal-oxide semiconductor field-effect transistor, a Fin FET may have a stronger short channel suppression capability and stronger operating current.

With further development of semiconductor technology, sizes of integrated circuit devices are getting smaller and smaller. Conventional Fin FETs may have limitations in further increasing operating current. Specifically, since only a region close to a top surface and a sidewall of a fin may be used as a channel region, in the fin, a volume used as the channel region may be small, and increase of operating current of a Fin FET may be limited. As such, a Fin FET with a channel gate-all-around (GAA) structure was proposed. In a Fin FET with a channel GAA structure, the volume used as the channel region may be increased, and the operating current may be increased.

However, in existing technology, performance of a Fin FET with a channel GAA structure needs to be improved.

### SUMMARY

The present disclosure provides a semiconductor structure and a method of forming the same, to improve performance of a fin field effect transistor (Fin FET) with a channel gate-all-around (GAA) structure.

To solve the above technical problems, the present disclosure provides a semiconductor structure. The semiconductor structure includes: a substrate; a vertical stack structure located over the substrate, where the vertical stack structure includes a channel region and a source/drain region located on two sides of the channel region, an arrangement direction of the channel region and the source/drain region is perpendicular to an extension direction of the vertical stack structure, the channel region includes a first stack region, an isolation region located over the first stack region, and a second stack region located over the isolation region, the first stack region includes a plurality of first channel layers vertically stacked, a first groove is located between adjacent first channel layers of the plurality of first channel layers and between a first channel layer of the plurality of first channel layers and the isolation region, the second stack region includes a plurality of second channel layers that are discrete, and a second groove is located between adjacent second channel layers of the plurality of second channel layers and between a second channel layer of the plurality of second channel layers and the isolation region; a first isolation layer located in the isolation region; a gate structure over the substrate, where the gate structure surrounds the first channel layer and the second channel layer, and the gate structure is also located in the first groove and the second groove; a first spacer located on a sidewall of the gate structure in the first groove, where the first spacer is located between the adjacent first channel layers and between the first channel layer and the first isolation layer, and the first spacer is flush with a sidewall of the first channel layer; a second spacer located on a sidewall of the gate structure in the second groove, where the second spacer is located between the adjacent second channel layers and between the second channel layer and the first isolation layer, and the second spacer is flush with a sidewall of the second channel layer; a first doped source/drain region located in the source/drain region on two sides of the first stack region; a first contact layer located on a surface of the first doped source/drain region, where the first contact layer has a first projection on a surface of the substrate; a second doped source/drain region located over the first contact layer, where the second doped source/drain region is located in the source/drain region on two sides of the second stack region; a second contact layer located on a surface of the second doped source/drain region, where the second contact layer has a second projection on the surface of the substrate, and an area of the first projection is greater than or equal to an area of the second projection; a second connection layer located on two sides of the gate structure, where the second connection layer is electrically connected to the second doped source/drain region through the second contact layer; and a first connection layer located in the second doped source/drain region on two sides of the gate structure, where the first connection layer is electrically connected to the first doped source/drain region through the first contact layer.

Optionally, the semiconductor structure includes a plurality of the vertical stack structures, and the plurality of the vertical stack structures is parallel to a first direction and arranged along a second direction, where the first direction and the second direction are parallel to the substrate surface, and the first direction is perpendicular to the second direction, and the gate structure spans a plurality of the channel regions, and the gate structure is parallel to the second direction.

Optionally, the semiconductor structure also includes a second isolation layer located between the first contact layer and the second doped source/drain region, where a top surface of the second isolation layer is lower than or flush with a top surface of the first isolation layer.

Optionally, the semiconductor structure also includes a first insulation layer located on a sidewall surface of the first connection layer, and a second insulation layer located on a sidewall surface of the second connection layer.

Optionally, for the first connection layer and the second connection layer located on a same side of the gate structure, a central axis, parallel to an extension direction of the gate structure, of the first connection layer coincides with a central axis, parallel to the extension direction of the gate structure, of the second connection layer.

Optionally, the central axes, parallel to the first direction, of the first connection layers located on two sides of the gate structure coincide, and the central axes, parallel to the first direction, of the second connection layers located on two sides of the gate structure coincide; or, for the first connection layer and the second connection layer located on two sides of the gate structure, the central axis, parallel to the first direction, of the first connection layer coincides with the central axis, parallel to the first direction, of the second connection layer.

Optionally, the semiconductor structure also includes a first spacer located on the sidewall of the gate structure in the first groove, where the first spacer is located between adjacent first channel layers and between the first channel layer and the first isolation layer, and the first spacer is flush with the sidewall of the first channel layer; and a second spacer located on the sidewall of the gate structure in the second groove, where the second spacer is located between adjacent second channel layers and between the second channel layer and the first isolation layer, and the second spacer is flush with the sidewall of the second channel layer.

Correspondingly, the present disclosure also provides a method of forming a semiconductor structure. The method includes: providing a substrate; forming a vertical stack structure located over the substrate, where the vertical stack structure includes a channel region and a source/drain region located on two sides of the channel region, an arrangement direction of the channel region and the source/drain region is perpendicular to an extension direction of the vertical stack structure, the channel region includes a first stack region located over the substrate, an isolation region located over the first stack region, and a second stack region located over the isolation region, the first stack region includes a plurality of first channel layers that are discrete, a first groove is located between adjacent first channel layers of the plurality of first channel layers and between a first channel layer of the plurality of first channel layers and the isolation region, the second stack region includes a plurality of second channel layers that are discrete, and a second groove is located between adjacent second channel layers of the plurality of second channel layers and between a second channel layer of the plurality of second channel layers and the isolation region; forming a first isolation layer located in the isolation region; forming a gate structure over the substrate, where the gate structure surrounds the first channel layer and the second channel layer, and the gate structure is also located in the first groove and the second groove; forming a first doped source/drain region in the source/drain region on two sides of the first stack region; forming a first contact layer on a surface of the first doped source/drain region, where the first contact layer has a first projection on a surface of the substrate; forming a second doped source/drain region over the first contact layer, where the second source/drain doping region is located in the source/drain region on two sides of the second stack region; forming a second contact layer on part or entire of a surface of the second doped source/drain region, where the second contact layer has a second projection on the surface of the substrate, and an area of the first projection is greater than or equal to an area of the second projection; forming a first connection layer in the second doped source/drain regions on two sides of the gate structure, where the first connection layer is electrically connected to the first doped source/drain region through the first contact layer; and forming a second connection layer on two sides of the gate structure, where the second connection layer is electrically connected to the second doped source/drain region through the second contact layer.

Optionally, a process of forming the vertical stack structure, the first isolation layer and the first doped source/drain region includes: forming a first composite material layer over the substrate, where the first composite material layer includes a plurality of first stack structures, and a first stacked structure of the plurality of first stack structures includes an initial first sacrificial layer and an initial first channel layer located on the initial first sacrificial layer; forming a second composite material layer over the first composite material layer, where the second composite material layer includes a plurality of second stack structures, and a second stacked structure of the plurality of second stack structures includes an initial second sacrificial layer and an initial second channel layer located over the initial second sacrificial layer; forming a dummy gate structure over the substrate, where the dummy gate structure spans the first composite material layer and the second composite material layer; removing part of the second composite material layer on two sides of the dummy gate structure until a surface of the initial first channel layer of the first composite material layer is exposed, and forming a first opening in the second composite material layer, such that the initial second sacrificial layer is formed into a second sacrificial layer, the initial second channel layer is formed into a second channel layer, and a second stack area is formed; removing a portion of the initial first channel layer exposed by the first opening, and forming a second opening at a bottom of the first opening, where the second opening is also located at a bottom of the second sacrificial layer, and the isolation region is formed; forming the first isolation layer in the second opening at the bottom of the second sacrificial layer; after forming the first isolation layer, removing the first composite material layer exposed by the second opening until the surface of the substrate is exposed, and forming a third opening in the first composite material layer, such that the initial first sacrificial layer is formed into a first sacrificial layer, the initial first channel layer is formed into a first channel layer, and the first stack region is formed; and forming the first doped source/drain region in the third opening.

Optionally, a process of forming the first contact layer includes: forming a first metal layer on the surface of the first doped source/drain region; and performing heat treatment on the first metal layer to form the first contact layer on the surface of the first doped source/drain region.

Optionally, before removing the portion of the initial first channel layer exposed by the first opening, the method also includes: forming an initial second spacer on a sidewall of the second sacrificial layer, where part of the initial second spacer is located between the second channel layers that are adjacent, and part of the initial second spacer is located on a sidewall of the second channel layer.

Optionally, after forming the first contact layer on the surface of the first doped source/drain region, the method also includes: forming a second isolation layer over the first contact layer, where a top surface of the second isolation layer is lower than or flush with a top surface of the first isolation layer.

Optionally, after forming the second isolation layer, the method also includes: removing the initial second spacer located on the sidewall of the second channel layer, and forming a second spacer on the sidewall of the second sacrificial layer, where the second spacer is located between the second channel layers that are adjacent, and the second spacer is flush with the sidewall of the second channel layer.

Optionally, a process of forming the second doped source/drain region includes: after forming the second spacer, forming the second doped source/drain region in the first opening.

Optionally, a process of forming the vertical stack structure and the gate structure includes: after forming the second doped source/drain region, forming a dielectric structure over the substrate, where the dummy gate structure is located in the dielectric structure; removing the dummy gate structure, and forming a gate opening in the dielectric structure, where the gate opening exposes the second sacrificial layer, the second channel layer, the first sacrificial layer and a sidewall surface of the first channel layer; removing the second sacrificial layer and the first sacrificial layer exposed by the gate opening, and forming a first groove between the first channel layers that are adjacent and between the first channel layer and the first isolation layer, forming a second groove between the second channel layers that are adjacent and between the second channel layer and the first isolation layer, and thus forming the vertical stack structure; and forming the gate structure in the gate opening, the first groove and the second groove.

Optionally, a process of forming the first connection layer, the second connection layer and the second contact layer includes: forming a third groove in the dielectric structure on two sides of the gate structure, where the third groove exposes part of the surface of the second doped source/drain region; forming the second contact layer on the surface of the second doped source/drain region exposed by the third groove; after the second contact layer is formed, forming a filling layer in the third groove; after the filling layer is formed, forming a fourth groove in the dielectric structure on two sides of the gate structure and in the second doped source/drain region, where the fourth groove exposes part of a surface of the first contact layer; removing the filling layer, and forming an insulation layer on a sidewall of the third groove and a sidewall of the fourth groove; and after forming the insulation layer, forming the second connection layer in the third groove, and forming the first connection layer in the fourth groove.

Optionally, a process of forming the second contact layer includes: forming a second metal layer on the surface of the second doped source/drain region, and performing heat treatment on the second metal layer to form the second contact layer.

Optionally, a process of forming the gate structure includes: after forming the second contact layer, forming a dielectric structure over the substrate, where the dummy gate structure is located in the dielectric structure; removing the dummy gate structure, and forming the gate structure in the dielectric structure.

Optionally, a process of forming the first connection layer and the second connection layer includes: forming a third groove in the dielectric structure on two sides of the gate structure, where the third groove exposes part of a surface of the second contact layer; forming a fourth groove in the dielectric structure on two sides of the gate structure and in the second doped source/drain region, where the fourth groove exposes part of a surface of the first contact layer; forming a second insulation layer on a sidewall of the third groove, and forming a first insulation layer on a sidewall of the fourth groove; and after forming the second insulation layer and the first insulation layer, forming the second connection layer in the third groove, and forming the first connection layer in the fourth groove.

Optionally, the semiconductor structure includes a plurality of the first composite material layers, where the plurality of the first composite material layers is parallel to a first direction and arranged along a second direction, the first direction and the second direction are parallel to the surface of the substrate, and the first direction is perpendicular to the second direction; the semiconductor structure includes a plurality of the second composite material layers, where each of the second composite material layers is located over the first composite material layers; the dummy gate structure spans the first composite material layers and the second composite material layers, and the dummy gate structure is parallel to the second direction.

Optionally, for the first connection layer and the second connection layer located on a same side of the gate structure, a central axis, parallel to an extension direction of the gate structure, of the first connection layer coincides with a central axis, parallel to the extension direction of the gate structure, of the second connection layer.

Optionally, central axes, parallel to a first direction, of the first connection layers located on two sides of the gate structure coincide, and central axes, parallel to the first direction, of the second connection layers located on two sides of the gate structure coincide; or, for the first connection layer and the second connection layer located on two sides of the gate structure, the central axis, parallel to the first direction, of the first connection layer coincides with the central axis, parallel to the first direction, of the second connection layer.

Optionally, before forming the first doped first doped source/drain region in the third opening, the method also includes: forming a first spacer on a sidewall of the first sacrificial layer, where the first spacer is located between the first channel layers that are adjacent, and the first spacer is flush with a sidewall of the first channel layer.

Optionally, a process of forming the first spacer includes: forming an initial first spacer on a sidewall of the first sacrificial layer, where part of the initial first spacer is located between the first channel layers that are adjacent, and part of the initial first spacers is located on the sidewall of the first channel layer; and removing the initial first spacer on the sidewall of the first channel layer, and forming the first spacer on the sidewall of the first sacrificial layer, where the first spacer is located between the first channel layers that are adjacent, and the first spacer is flush with the sidewall of the first channel layer.

Optionally, a process of forming the second contact layer includes: forming a second metal layer on the surface of the second doped source/drain region, and performing heat treatment on the second metal layer to form the second contact layer.

Compared with existing technology, technical solutions of the present disclosure have operation current the following beneficial effects:

In the method of forming a semiconductor structure provided by the present disclosure, after forming the first doped source/drain region, a first contact layer is formed on the surface of the first doped source/drain region. The first contact layer has a first projection on the substrate surface. Then, after forming the second doped source/drain region, a second contact layer is formed on the surface of the second doped source/drain region. The second contact layer has a second projection on the substrate surface. An area of the first projection is greater than or equal to an area of the second projection. The first contact layer and the second contact layer are not formed simultaneously. Since the first contact layer may be located on an entire surface of the first doped source/drain region, the area of the first projection of the first contact layer may be greater than or equal to the area of the second projection of the second contact layer. As such, the overall area of the first contact layer and the second contact layer in the semiconductor structure may be large. The first contact layer and the second contact layer may have electrical conductivity. Accordingly, electrical resistance of the semiconductor structure may be reduced.

Further, for the first connection layer and the second connection layer located on a same side of the gate structure, the central axis, parallel to the extension direction of the gate structure, of the first connection layer coincides with the central axis, parallel to the extension direction of the gate structure, of the second connection layer. The first connection layer and the second connection layer on a same side of the gate structure may be arranged parallel to the extending direction of the gate structure. Accordingly, when the first connection layer and the second connection layer are electrically isolated, the first connection layer and the second connection layer may occupy a small space in the first direction, and the size of the semiconductor structure may be reduced.

Further, the central axes, parallel to the first direction, of the first connection layers located on two sides of the gate structure coincide, and the central axes, parallel to the first direction, of the second connection layers located on two sides of the gate structure coincide; or, the central axis, parallel to the first direction, of the first connection layer coincides with the central axis, parallel to the first direction, of the second connection layer, where the first connection layer and the second connection layer located on two sides of the gate structure. Accordingly, the first connection layer and the second connection layer located on two sides of the gate structure have good arrangement flexibility. Arrangement of the first connection layer and the second connection layer may be adjusted according to design requirements and performance requirements of the semiconductor structure. In addition, when the first connection layer and the second connection layer are located on two sides of the gate structure, and the central axis, parallel to the first direction, of the first connection layer coincides with the central axis, parallel to the first direction, of the second connection layer, the first connection layer is electrically connected to the first doped source/drain region, and the second connection layer is electrically connected to the second doped source/drain region. Accordingly, circuit current taken out from the first connection layer and circuit current taken out from the second connection layer may have good uniformity.

Further, the sidewall of the fourth groove has a first insulation layer. As such, the first connection layer located in the fourth groove may be electrically isolated from the second doped source/drain region. Accordingly, a short circuit due to direct contact between the first connection layer and the second doped source/drain region may be avoided.

### BRIEF DESCRIPTION OF THE DRAWINGS

FIG. 1 and FIG. 2 illustrate structural schematic diagrams of a semiconductor structure;

FIGS. 3 to 21 illustrate cross-sectional structural schematic diagrams corresponding to certain stages of an exemplary process of forming a semiconductor structure, consistent with the disclosed embodiments of the present disclosure;

FIGS. 22 to 24 illustrate cross-sectional structural schematic diagrams corresponding to certain stages of another exemplary process of forming a semiconductor structure, consistent with the disclosed embodiments of the present disclosure;

FIG. 25 illustrates a cross-sectional structural schematic diagram corresponding to a certain stage of another exemplary process of forming a semiconductor structure, consistent with the disclosed embodiments of the present disclosure; and

FIG. 26 illustrates a flowchart of an exemplary process of forming a semiconductor structure, consistent with the disclosed embodiments of the present disclosure.

### DETAILED DESCRIPTION

As mentioned in the background, in existing technology, performance of a Fin FET with a channel gate-all-around (GAA) structure needs to be improved. Analysis and description will now be carried out with reference to specific embodiments.

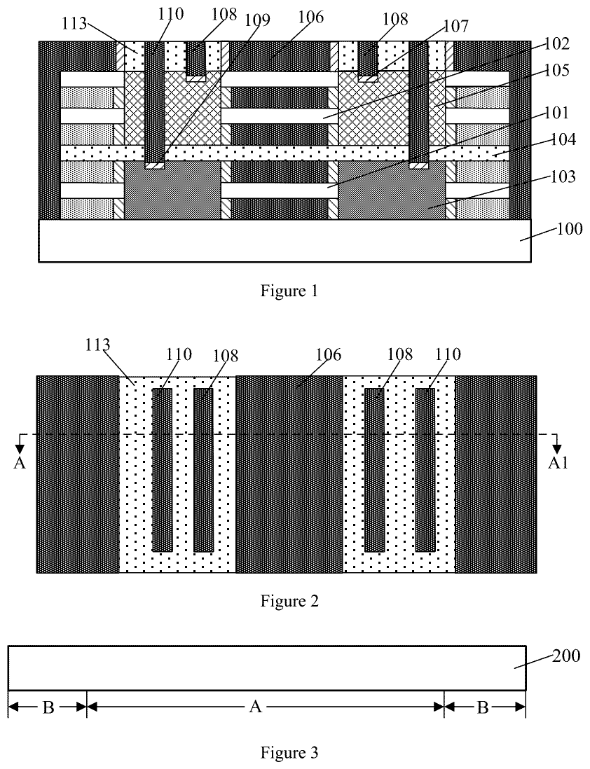

FIG. 1 and FIG. 2 illustrate structural schematic diagrams of a semiconductor structure.

FIG. 2 is a top view of FIG. 1, and FIG. 1 is a schematic view of FIG. 2 along section line AA1. Referring to FIGS. 1 and 2, the semiconductor structure includes: a substrate 100; a first nanostructure located over the substrate 100, where the first nanostructure includes a plurality of discrete first channel layers 101; an isolation structure 104 located over the first nanostructure; a second nanostructure located over the isolation structure 104, where the second nanostructure includes a plurality of discrete second channel layers 102; a third groove located between adjacent first channel layers 101 and between the first channel layer 101 and the isolation structure 104; a fourth groove located between adjacent second channel layers 102 and between the second channel layer 102 and the isolation structure 104; a gate structure 106 located over the substrate 100, where the gate structure 106 surrounds the first nanostructure and the second nanostructure, and the gate structure 106 is also located in the third groove and the fourth groove; a doped source/drain region 103 located in the first nanostructure on two sides of the gate structure 106; a first contact layer 109 located on a surface of the first doped source/drain region 103; a second doped source/drain region 105 located over the isolation structure 104, where the second doped source/drain region 105 is located in the second nanostructure on two sides of the gate structure 106; a second contact layer 107 located over the second doped source/drain region 105; a dielectric structure 113 located over the second doped source/drain region 105; a second connection layer 108 located in the dielectric structure 113 on two sides of the gate structure 106, where the second connection layer 108 is electrically connected to the second doped source/drain region 105 through the second contact layer 107; a first connection layer 110 located in the dielectric structure 113 on two sides of the gate structure 106 and in the second doped source/drain region 105, where the first connection layer 110 is electrically connected to the first doped source/drain region 103 through the first contact layer 109. The first connection layer 110 and the second connection layer 108 are parallel to the extending direction of the gate structure 106.

During a process of forming the semiconductor structure, the first connection layer 110 and the second connection layer 108 are usually formed simultaneously after the second doped source/drain region 105 is formed. The first connection layer 110 and the second connection layer 108 are parallel to the extending direction of the gate structure 106. A method of forming the first connection layer 110 and the second connection layer 108 includes: forming a first groove (not shown) in the dielectric structure 113 on two sides of the gate structure 106 and in the second doped source/drain region 105, where the first groove exposes part of the surface of the first doped source/drain region 103; forming a second groove (not shown) in the dielectric structure 113 on two sides of the gate structure 106, where the second groove exposes part of the surface of the second doped source/drain region 105; forming the first contact layer 109 on a surface of the first doped source/drain region 103 exposed in the first groove, and forming the second contact layer 107 on a surface of the second doped source/drain region 105 exposed in the second groove; and forming the first connection layer 110 in the first groove, and forming the second connection layer 108 in the second groove.

The first connection layer 110 and the second connection layer 108 may be formed simultaneously. The first contact layer 109 is located at the bottom of the first groove, and the second contact layer 107 is located at the bottom of the second groove. As such, the areas of the first contact layer 109 and the second contact layer 107 may each be small. Accordingly, the contact resistance between the first connection layer 110 and the first doped source/drain region 103 may be relatively large, and the contact resistance between the second connection layer 108 and the second doped source/drain region 105 may be relatively large.

To solve the above problems, the present disclosure provides a semiconductor structure and a method for forming the semiconductor structure. After forming the first doped source/drain region, a first contact layer is formed on the surface of the first doped source/drain region. The first contact layer has a first projection on the substrate surface. Then, after forming the second doped source/drain region, a second contact layer is formed on the surface of the second doped source/drain region. The second contact layer has a second projection on the substrate surface. An area of the first projection is greater than or equal to an area of the second projection. The first contact layer and the second contact layer are not formed simultaneously. Since the first contact layer may be located on an entire surface of the first doped source/drain region, the area of the first projection of the first contact layer may be greater than or equal to the area of the second projection of the second contact layer. As such, the overall area of the first contact layer and the second contact layer in the semiconductor structure may be large. The first contact layer and the second contact layer may have electrical conductivity. Accordingly, electrical resistance of the semiconductor structure may be reduced.

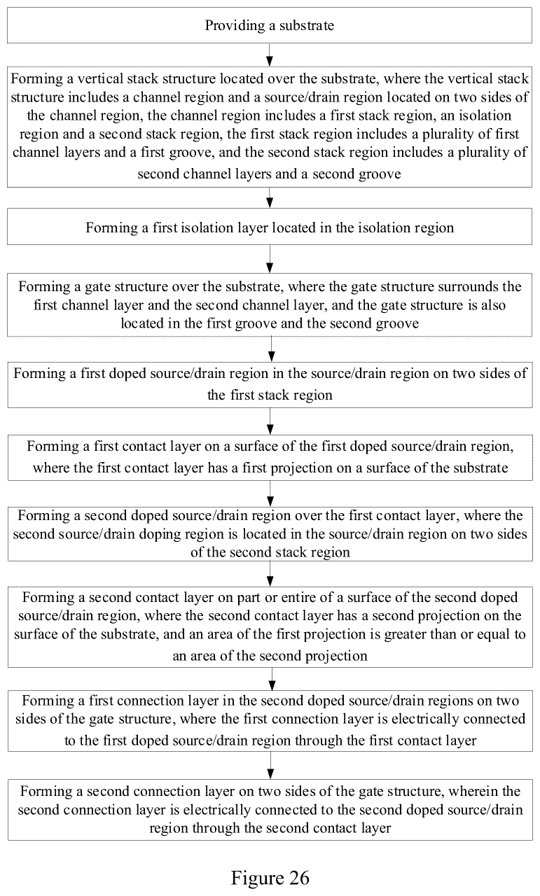

FIGS. 3 to 21 illustrate cross-sectional structural schematic diagrams corresponding to certain stages of an exemplary process of forming a semiconductor structure, consistent with the disclosed embodiments of the present disclosure. FIG. 26 illustrates a flowchart of an exemplary process of forming a semiconductor structure, consistent with the disclosed embodiments of the present disclosure.

Referring to FIG. 3 and FIG. 26, a substrate 200 is provided.

The substrate 200 includes an active area A and an inactive area B located on two sides of the active area A.

In one embodiment, the substrate 200 is made of a material including silicon.

In some other embodiments, the substrate is made of a material including silicon carbide, silicon germanium, multi-element semiconductor material composed of III-V group elements, silicon on insulator (SOI) or germanium on insulator (GOI), or a combination thereof. The multi-component semiconductor material composed of III-V group elements includes InP, GaAs, GaP, InAs, InSb, InGaAs, InGaAsP or a combination thereof.

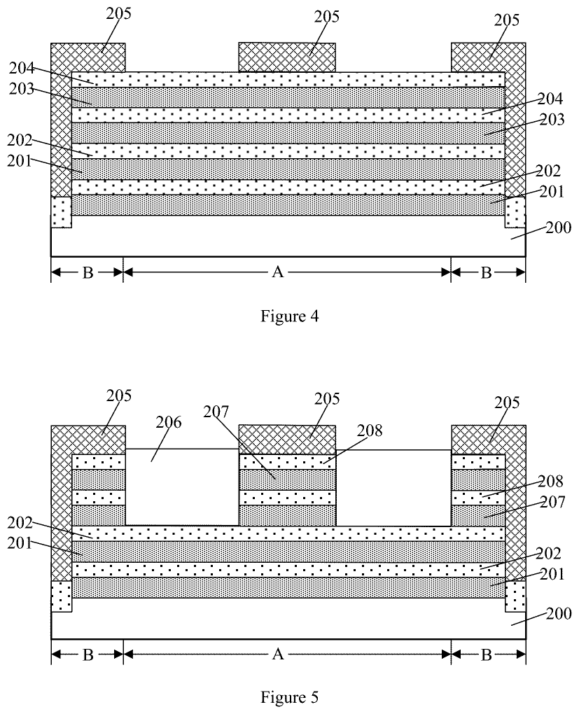

Referring to FIG. 26, a vertical stack structure is formed over the substrate. The vertical stack structure over the active area A includes a channel region and a source/drain region located on two sides of the channel region. An arrangement direction of the channel region and the source/drain region is perpendicular to the extension direction of the vertical stack structure. The channel region includes a first stack region located over the substrate, an isolation region located over the first stack region, and a second stack region located over the isolation region. The first stack region includes a plurality of discrete first channel layers, with a first groove located between adjacent first channel layers and between the first channel layer and the isolation region. The second stack region includes a plurality of discrete second channel layers, with a second groove located between adjacent second channel layers and between the second channel layer and the isolation region. For a process of forming the vertical stack structure, reference may be made to FIGS. 4-14.

In one embodiment, the semiconductor structure includes a plurality of the vertical stack structures. The plurality of the vertical stack structures is parallel to a first direction and arranged along a second direction. The first direction and the second direction are parallel to the substrate surface, and the first direction is perpendicular to the second direction.

Referring to FIG. 4, a first composite material layer is formed over the substrate 200. The first composite material layer includes a plurality of first stack structures. The first stacked structure includes an initial first sacrificial layer 201 and an initial first channel layer 202 located on the initial first sacrificial layer 201. A second composite material layer is formed over the first composite material layer. The second composite material layer includes a plurality of second stack structures. The second stacked structure includes an initial second sacrificial layer 203 and an initial second channel layer 204 located on the initial second sacrificial layer 203.

In one embodiment, the semiconductor structure includes a plurality of the first composite material layers. The plurality of the first composite material layers is parallel to the first direction and arranged along the second direction. The first direction and the second direction are parallel to the surface of the substrate 200, and the first direction is perpendicular to the second direction. The semiconductor structure includes a plurality of the second composite material layers. The plurality of the second composite material layers is each located over the first composite material layers.

The initial first sacrificial layer 201 and the initial first channel layer 202 may be made of different materials. As such, when the initial first sacrificial layer 201 is subsequently removed, the removal process may cause little damage to the initial first channel layer 202. The initial second sacrificial layer 203 and the initial second channel layer 204 may be made of different materials. As such, when the initial second sacrificial layer 203 is subsequently removed, the removal process may cause little damage to the initial second channel layer 204.

In one embodiment, the initial first sacrificial layer 201 and the initial second sacrificial layer 203 may be made of a material including silicon germanium. The initial first channel layer 202 and the initial second channel layer 204 may be made of a material including silicon.

In one embodiment, the conductivity type of the initial first channel layer 202 is P type, and the conductivity type of the initial second channel layer 204 is N type.

In some other embodiments, the conductivity type of the initial first channel layer is N-type, and the conductivity type of the initial second channel layer is P-type.

Still referring to FIG. 4, a dummy gate structure 205 may be formed over the substrate 200. The dummy gate structure 205 spans the first composite material layer and the second composite material layer over the active area A. The dummy gate structure 205 also spans the first composite material layer and the second composite material layer over the inactive region B.

In one embodiment, the dummy gate structure 205 is parallel to the second direction.

The dummy gate structure 205 includes a dummy gate dielectric layer (not shown) and a dummy gate layer (not shown) located over the dummy gate dielectric layer. The dummy gate dielectric layer is made of a material including silicon oxide or low-K (K less than 3.9) materials. The dummy gate layer may be made of a material including polysilicon.

Referring to FIG. 5, part of the second composite material layer on two sides of the dummy gate structure 205 in the active area A may be removed until the surface of the initial first channel layer 202 of the first composite material layer is exposed. A first opening 206 is thus formed in the second composite material layer. Accordingly, the initial second sacrificial layer 203 is formed into a second sacrificial layer 207, the initial second channel layer 204 is formed into a second channel layer 208, and a second stack area is formed.

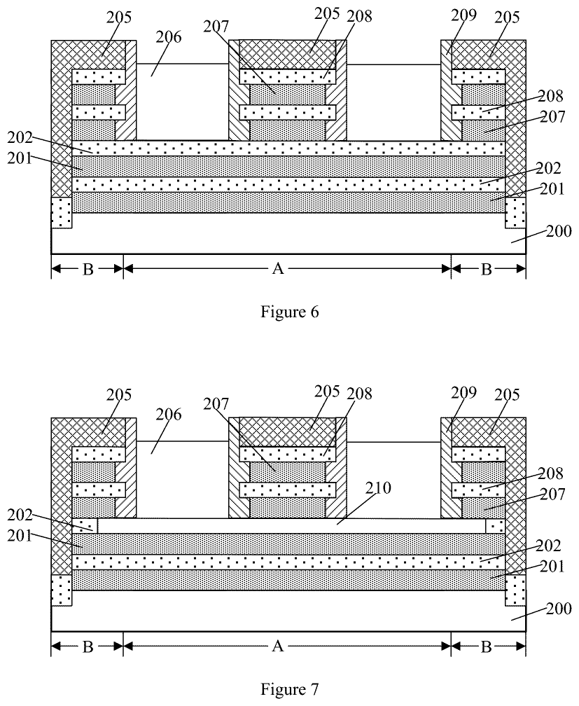

Referring to FIG. 6, an initial second spacer 209 may be formed on a sidewall of the second sacrificial layer 207. Part of the initial second spacer 209 is located between adjacent second channel layers 208, and part of the initial second spacers 209 is located on a sidewall of the second channel layer 208.

A method of forming the initial second spacer 209 includes: removing a portion of the second sacrificial layer 207 exposed by the first opening 206 to form a groove (not shown) between adjacent second channel layers 208; form a spacer material layer (not shown) on the sidewall of the second channel layer 208, in the groove, and over the surface of the initial first channel layer 202; and etching back the spacer material layer until the surface of the initial first channel layer 202 is exposed, to form the initial second spacer 209.

The initial second spacer 209 is made of a material including a dielectric material. The dielectric material includes silicon oxide, silicon nitride, silicon carbide, silicon oxycarbide, silicon oxynitride, aluminum oxide, aluminum nitride, silicon oxynitride, silicon oxynitride, or a combination thereof.

In one embodiment, the initial second spacer 209 is made of a material including silicon nitride.

Referring to FIG. 7, after the initial second spacer 209 is formed, the portion of the initial first channel layer 202 exposed by the first opening 206 may be removed, and a second opening 210 may be formed at the bottom of the first opening 206. The second opening 210 is also located at the bottom of the second sacrificial layer 207, and the isolation region is formed.

A method of forming the second opening 210 includes: with the initial second spacer 209 as a mask, etching the initial first channel layer 202 until the surface of the initial first sacrificial layer 201 is exposed to form an initial second opening (not shown); and removing the initial first channel layer 202 at the bottom of the second sacrificial layer 207 by lateral etching to form the second opening 210.

In one embodiment, part of the second opening 210 is also located in the invalid area B.

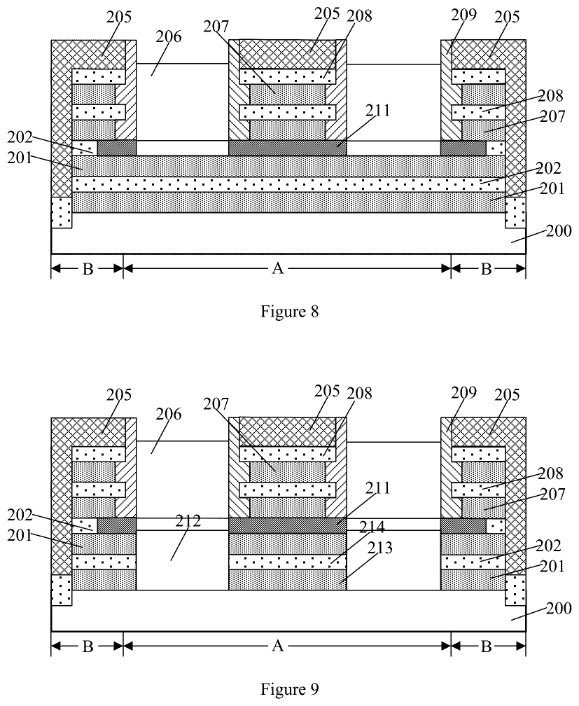

Referring to FIG. 8, a first isolation layer 211 may be formed in the second opening 210 at the bottom of the second sacrificial layer 207. The first isolation layer 211 is located in the isolation region.

A method of forming the first isolation layer 211 includes: forming an isolation material layer (not shown) in the second opening 210; removing the isolation material layer at the bottom of the first opening 206, thus forming the first isolation layer 211, in the second opening 210, at the bottom of the second sacrificial layer 207.

In one embodiment, part of the first isolation layer 211 is also located over the invalid area B.

The first isolation layer 211 is made of a material including a dielectric material. The dielectric material includes silicon oxide, silicon nitride, silicon carbide, silicon oxycarbide, silicon oxynitride, aluminum oxide, aluminum nitride, silicon oxynitride, silicon oxynitride, or a combination thereof.

In one embodiment, the first isolation layer 211 is made of a material including silicon oxide.

Referring to FIG. 9, after forming the first isolation layer 211, the first composite material layer exposed by the second opening 210 may be removed until the surface of the substrate 200 is exposed, forming a third opening 212 in the first composite material layer. As such, the initial first sacrificial layer 201 is formed into a first sacrificial layer 213, the initial first channel layer 202 is formed into a first channel layer 214, and the first stack region is thus formed.

A method of removing the first composite material layer exposed by the second opening 210 includes: with the initial second spacer 209 as a mask, etching the first composite material layer.

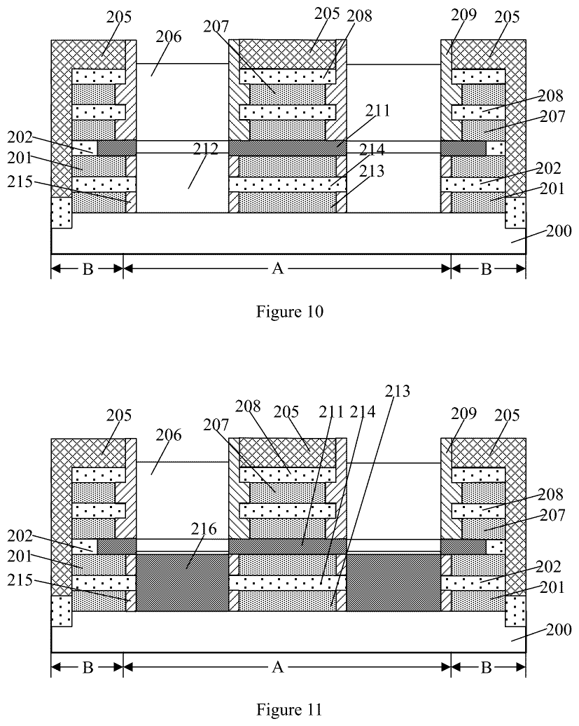

Referring to FIG. 10, a first spacer 215 may be formed on the sidewall of the first sacrificial layer 213. The first spacer 215 is located between adjacent first channel layers 214, and the first spacer 215 are flush with the sidewall of the first channel layer 214.

A method of forming the first side wall 215 includes: removing the portion of the first sacrificial layer 213 exposed by the third opening 212, thus forming a groove (not shown) on the sidewall of the first sacrificial layer 213; forming an initial first spacer (not shown) in the groove of the sidewall of the first sacrificial layer 213, where part of the initial first spacer is located between adjacent first channel layers 214, and part of the initial first spacers is located on the sidewall of the first channel layer 214; and removing the initial first spacer on the sidewall of the first channel layer 214, thus forming the first spacer 215 on the sidewall of the first sacrificial layer 213. The first spacer 215 is located between adjacent first channel layers 214, and the first spacer 215 is flush with the sidewall of the first channel layer 214.

The first spacer 215 is made of a material including a dielectric material. The dielectric material includes silicon oxide, silicon nitride, silicon carbide, silicon oxycarbide, silicon oxynitride, aluminum oxide, aluminum nitride, silicon oxynitride, silicon oxynitride, or a combination thereof.

In one embodiment, the first spacer 215 is made of a material including silicon nitride.

Referring to FIG. 11, a first doped source/drain region 216 may be formed in the third opening 212. The first doped source/drain region 216 is located in the source/drain region on two sides of the first stack region.

The first doped source/drain region 216 is made of a material including silicon germanium or phosphorus silicon. In one embodiment, the first doped source/drain region 216 is made of a material including silicon germanium. The first doped source/drain region 216 may be used to form a P-type device.

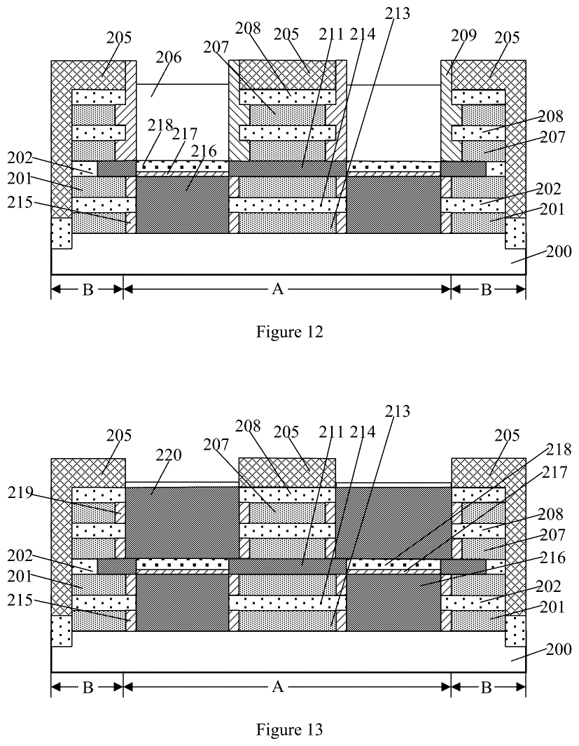

Referring to FIG. 12, a first contact layer 217 may be formed on the surface of the first doped source/drain region 216. The first contact layer 217 has a first projection on the surface of the substrate 200.

A method of forming the first contact layer 217 includes: forming a first metal layer (not shown) on the surface of the first doped source/drain region 216; and performing heat treatment on the first metal layer to form the first contact layer 217 on the surface of the first doped source/drain region 216.

Since the first doped source/drain region 216 is made of a material including silicon germanium, the first metal layer and the surface of the first doped source/drain region 216 may form the first contact layer 217 after heat treatment.

The first contact layer 217 is made of a material including metal silicide, and the metal silicide includes tungsten silicide.

Still referring to FIG. 12, a second isolation layer 218 may be formed over the first contact layer 217. A top surface of the second isolation layer 218 is lower than or flush with a top surface of the first isolation layer 211.

A method of forming the second isolation layer 218 includes: forming an isolation material layer (not shown) over the first contact layer 217; and etching back the isolation material layer to form the second isolation layer 218.

The second isolation layer 218 is made of a material including a dielectric material. The dielectric material includes silicon oxide, silicon nitride, silicon carbide, silicon oxycarbide, silicon oxynitride, aluminum oxide, aluminum nitride, silicon oxynitride, silicon oxynitride, or a combination thereof.

In one embodiment, the second isolation layer 218 is made of a material including silicon oxide.

Referring to FIG. 13, the initial second spacer 209 located on the sidewall of the second channel layer 208 may be removed, and a second spacer 219 may be formed on the sidewall of the second sacrificial layer 207. The second spacer 219 is located between adjacent second channel layers 208, and the second spacer 219 is flush with the sidewall of the second channel layer 208.

Still referring to FIG. 13, after forming the second spacer 219, a second doped source/drain region 220 may be formed in the first opening 206 over the second isolation layer 218. The second source/drain doping region 220 is located in the source/drain region on two sides of the second stack region.

The second doped source/drain region 220 is made of a material including silicon germanium or phosphorus silicon. In one embodiment, the second doped source/drain region 220 is made of a material including phosphorus silicon, and the second doped source/drain region 220 may be used to form an N-type device.

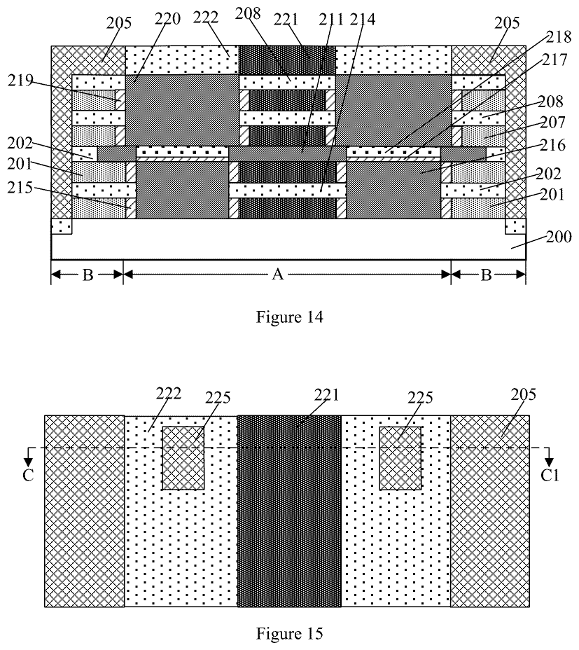

Referring to FIG. 14, a gate structure 221 may be formed over the substrate. The gate structure 221 surrounds the first channel layer 214 and the second channel layer 208. The gate structure 221 is also located in the first groove and the second groove.

A method of forming the vertical stack structure and the gate structure includes: after forming the second doped source/drain region 220, forming a dielectric structure 222 over the substrate 200, where the dummy gate structure 205 is located in the dielectric structure 222; removing the dummy gate structure 205, thus forming a gate opening (not shown) in the dielectric structure 222, where the gate opening exposes the second sacrificial layer 207, the second channel layer 208, the first sacrificial layer 213 and the sidewall surface of the first channel layer 214; removing the second sacrificial layer 207 and the first sacrificial layer 213 exposed by the gate opening, forming a first groove (not shown) between adjacent first channel layers 214 and between the first channel layer 214 and the first isolation layer 211, forming a second groove (not shown) between adjacent second channel layers 208 and between the second channel layer 208 and the first isolation layer 211, and forming the vertical stack structure; and forming the gate structure 221 in the gate opening, the first groove and the second groove.

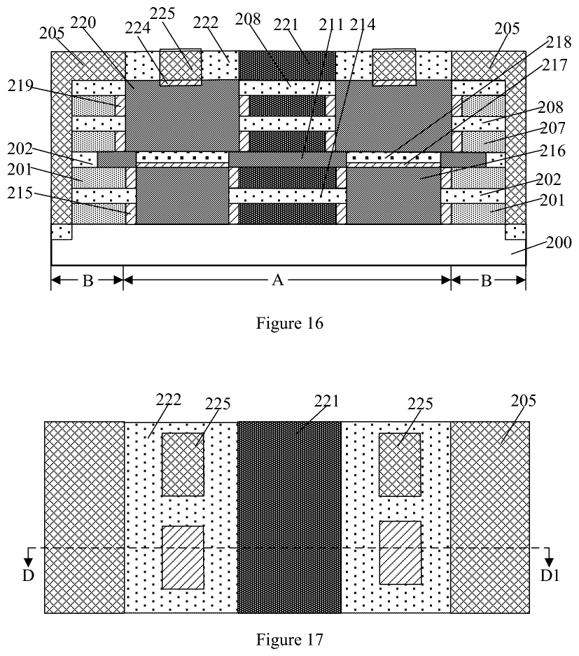

FIG. 15 is a top view of FIG. 16, and FIG. 16 is a schematic cross-sectional structural diagram of FIG. 15 along the direction of section line CC1. Referring to FIGS. 15 and 16, a second contact layer 224 may be formed on part or entire of the surface of the second doped source/drain region 220. The second contact layer 224 has a second projection on the surface of the substrate 200. An area of the first projection is greater than or equal to an area of the second projection.

A method of forming the second contact layer 224 includes: forming a third groove (not shown) in the dielectric structure 222 on two sides of the gate structure 221, where the third groove exposes part of the surface of the second doped source/drain region 220; forming a second metal layer (not shown) on the surface of the second doped source/drain region 220 exposed in the third groove; and performing heat treatment on the second metal layer to form the second contact layer 224 on the surface of the second doped source/drain region 220.

Since the second doped source/drain region 220 is made of a material including phosphorus silicon, the second metal layer and the surface of the second doped source/drain region 220 may form the second contact layer 224 after heat treatment.

The second contact layer 224 is made of a material including metal silicide. The metal silicide includes tungsten silicide.

The first contact layer 217 and the second contact layer 224 may not be formed simultaneously. Since the first contact layer 217 may be located on the entire surface of the first doped source/drain region 216, the area of the first projection of the first contact layer 217 may be greater than or equal to the area of the second projected of the second contact layer 224. Accordingly, the overall area of the first contact layer 217 and the second contact layer 224 in the semiconductor structure may be large. The first contact layer 217 and the second contact layer 224 are conductive. Accordingly, the resistance of the semiconductor structure may be reduced.

Still referring to FIGS. 15 and 16, after the second contact layer 224 is formed, a filling layer 225 may be formed in the third groove.

The filling layer 225 is made of a material including an amorphous material. The amorphous material may include amorphous carbon or amorphous silicon, such that the amorphous material may be removed later.

Next, a second connection layer may be formed on two sides of the gate structure 221. The second connection layer is electrically connected to the second doped source/drain region 220 through the second contact layer 224. A first connection layer may be formed in the second doped source/drain regions 220 on two sides of the gate structure 221. The first connection layer is electrically connected to the first doped source/drain region 216 through the first contact layer 217. For a process of forming the first connection layer and the second connection layer, reference may be made to FIGS. 17 to 21.

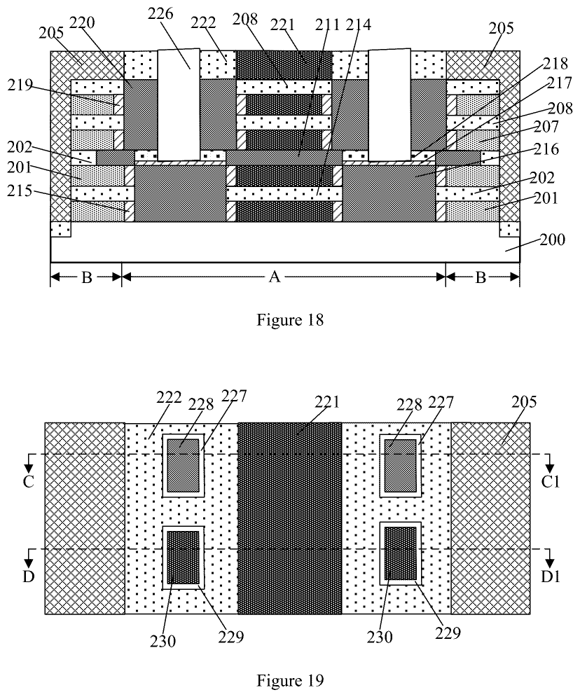

FIG. 17 is a top view of FIG. 18, and FIG. 18 is a schematic cross-sectional structural diagram along the section line DD1 in FIG. 17. Referring to FIGS. 17 and 18, after forming the filling layer 225, a fourth groove 226 may be formed in the dielectric structure 222 on two sides of the gate structure 221 and in the second doped source/drain region 220. The fourth groove 226 exposes part of the surface of the first contact layer 217.

A method of forming the fourth groove 226 includes: forming a patterned layer (not shown) on the dielectric structure 222; using the patterned layer as a mask to etch the dielectric structure 222, the second doped source/drain region 220, and the second isolation layer 218 until the surface of the first contact layer 217 is exposed, thus forming the fourth groove 226.

A process of etching the dielectric structure 222, the second doped source/drain region 220, and the second isolation layer 218 includes a dry etching process.

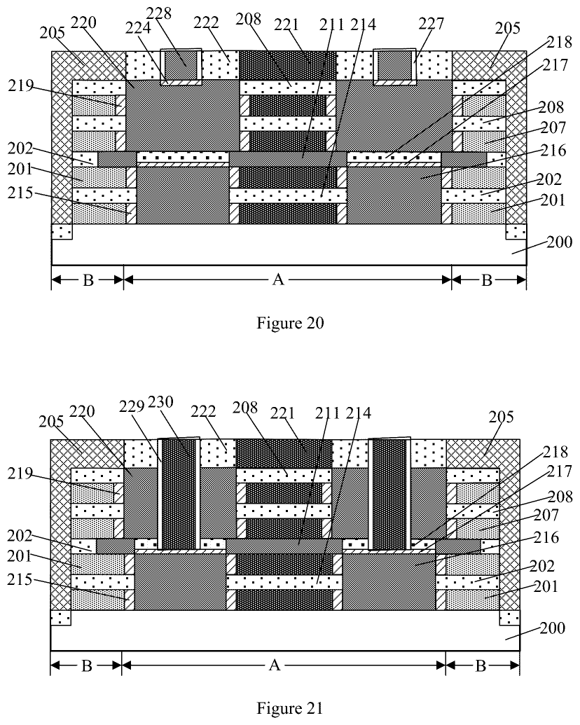

FIG. 19 is a top view of FIGS. 20 and 21. FIG. 20 is a schematic cross-sectional structural diagram along the section line CC1 in FIG. 19. FIG. 21 is a schematic cross-sectional structural diagram along the section line DD1 in FIG. 19. Referring to FIGS. 19-21, the filling layer 225 may be removed. After removing the filling layer 225, a second insulation layer 227 may be formed on the sidewall of the third groove, and a first insulation layer 229 may be formed on the sidewall of the fourth groove 226. After forming the second insulation layer 227 and the first insulation layer 229, a second connection layer 228 may be formed in the third groove, and a first connection layer 230 may be formed in the fourth groove 226.

A method of forming the second insulation layer 227 and the first insulation layer 229 includes: forming a sidewall material layer (not shown) on the sidewall surface and bottom surface of the third groove, and the sidewall surface and bottom surface of the fourth groove 226; and etching back the sidewall material layer until the sidewall material layer on the bottom surface of the third groove and the bottom surface of the fourth groove 226 is removed, thus forming the second insulation layer 227 on the sidewall of the third groove, and forming the first insulation layer 229 on the sidewall of the fourth groove 226.

The second insulation layer 227 and the first insulation layer 229 are made of a material including dielectric materials. The dielectric material includes silicon oxide, silicon nitride, silicon carbide, silicon oxycarbide, silicon oxynitride, aluminum oxide, aluminum nitride, silicon oxynitride, silicon oxynitride, or a combination thereof.

In one embodiment, the second insulation layer 227 and the first insulation layer 229 are made of a material including silicon nitride.

The sidewall of the fourth groove 226 has a first insulation layer 229. As such, the first connection layer 230 located in the fourth groove 226 may be electrically isolated from the second doped source/drain region 220. Accordingly, a short circuit due to direct contact between the first connection layer 230 and the second doped source/drain region 220 may be avoided.

In one embodiment, the central axes, parallel to the first direction, of the first connection layers 230 located on two sides of the gate structure 221 coincide, and the central axes, parallel to the first direction, of the second connection layers 228 located on two sides of the gate structure 221 coincide.

In some other embodiments, for the first connection layer and the second connection layer located on two sides of the gate structure, the central axis, parallel to the first direction, of the first connection layer coincides with the central axis, parallel to the first direction, of the second connection layer.

The central axes, parallel to the first direction, of the first connection layers 230 located on two sides of the gate structure 221 coincide, and the central axes, parallel to the first direction, of the second connection layers 228 located on two sides of the gate structure 221 coincide; or, the central axis, parallel to the first direction, of the first connection layer coincides with the central axis, parallel to the first direction, of the second connection layer, where the first connection layer and the second connection layer located on two sides of the gate structure. Accordingly, the first connection layer 230 and the second connection layer 228 located on two sides of the gate structure 221 have good arrangement flexibility. Arrangement of the first connection layer 230 and the second connection layer 228 may be adjusted according to design requirements and performance requirements of the semiconductor structure.

In one embodiment, for the first connection layer 230 and the second connection layer 228 located on a same side of the gate structure 221, the central axis, parallel to the extension direction of the gate structure 221, of the first connection layer 230 coincides with the central axis, parallel to the extension direction of the gate structure 221, of the second connection layer 228.

The first connection layer 230 and the second connection layer 228 on a same side of the gate structure 221 may be arranged parallel to the extending direction of the gate structure 221. Accordingly, when the first connection layer 230 and the second connection layer 228 are electrically isolated, the first connection layer 230 and the second connection layer 228 may occupy a small space in the first direction, and the size of the semiconductor structure may be reduced.

Correspondingly, the present disclosure also provides a semiconductor structure. Still referring to FIGS. 19-21, the semiconductor structure includes:
a substrate 200;
a vertical stack structure located over the substrate 200, where the vertical stack structure includes a channel region and a source/drain region located on two sides of the channel region, an arrangement direction of the channel region and the source/drain region is perpendicular to an extension direction of the vertical stack structure, the channel region includes a first stack region, an isolation region located over the first stack region, and a second stack region located over the isolation region, the first stack region includes a plurality of discrete first channel layers 214, with first grooves located between adjacent first channel layers and between the first channel layer and the isolation region, and the second stack region includes a plurality of discrete second channel layers 206, with second grooves located between adjacent second channel layers 208 and between the second channel layer and the isolation region;
a first isolation layer 211 located in the isolation region;
a gate structure 221 over the substrate 200, where the gate structure 221 surrounds the first channel layer 214 and the second channel layer 208, and the gate structure 221 is also located in the first groove and the second groove;
a first doped source/drain region 216 located in the source/drain region on two sides of the first stack region;
a first contact layer 217 located on the surface of the first doped source/drain region 216, where the first contact layer 217 has a first projection on the surface of the substrate 200;
a second doped source/drain region 220 located over the first contact layer 217, where the second doped source/drain region 220 is located in the source/drain region on two sides of the second stack region;
a second contact layer 224 located on the surface of the second doped source/drain region 220, where the second contact layer 224 has a second projection on the surface of the substrate 200, and the area of the first projection is greater than or equal to the area of the second projection;
a second connection layer 228 located on two sides of the gate structure 221, where the second connection layer 228 is electrically connected to the second doped source/drain region 220 through the second contact layer 224; and
a first connection layer 230 located in the second doped source/drain region 220 on two sides of the gate structure 221, where the first connection layer 230 is electrically connected to the first doped source/drain region 216 through the first contact layer 217.

In one embodiment, the semiconductor structure includes a plurality of the vertical stack structures. The plurality of the vertical stack structures is parallel to a first direction and arranged along a second direction. The first direction and the second direction are parallel to the substrate surface, and the first direction is perpendicular to the second direction. The gate structure 221 spans a plurality of the channel regions, and the gate structure 221 is parallel to the second direction.

In one embodiment, the semiconductor structure also includes: a second isolation layer 218 located between the first contact layer 217 and the second doped source/drain region 220. A top surface of the second isolation layer 218 is lower than or flush with a top surface of the first isolation layer 211.

In one embodiment, the semiconductor structure also includes: a first insulation layer 229 located on a sidewall surface of the first connection layer 230, and a second insulation layer 227 located on a sidewall surface of the second connection layer 228.

In one embodiment, for the first connection layer 230 and the second connection layer 228 located on a same side of the gate structure 221, the central axis, parallel to the extension direction of the gate structure 221, of the first connection layer 230 coincides with the central axis, parallel to the extension direction of the gate structure 221, of the second connection layer 228.

In one embodiment, the central axes, parallel to the first direction, of the first connection layers 230 located on two sides of the gate structure 221 coincide, and the central axes, parallel to the first direction, of the second connection layers 228 located on two sides of the gate structure 221 coincide.

In some other embodiments, for the first connection layer and the second connection layer located on two sides of the gate structure, the central axis, parallel to the first direction, of the first connection layer coincides with the central axis, parallel to the first direction, of the second connection layer.

In one embodiment, the semiconductor structure also includes: a first spacer 215 located on the sidewall of the gate structure 221 in the first groove, where the first spacer 215 is located between adjacent first channel layers 214 and between the first channel layer 214 and the first isolation layer 211, and the first sidewall 215 is flush with the sidewall of the first channel layer 214; a second spacer 219 located on the sidewall of the gate structure 221 in the second groove, where the second spacer 219 is located between adjacent second channel layers 208 and between the second channel layer 208 and the first isolation layer 211, and the second spacer 219 is flush with the sidewall of the second channel layer 208.

In one embodiment, the conductivity type of the first channel layer 214 is N-type, and the conductivity type of the second channel layer 208 is P type; or, the conductivity type of the first channel layer 214 is P type, and the conductivity type of the second channel layer 208 is N type.

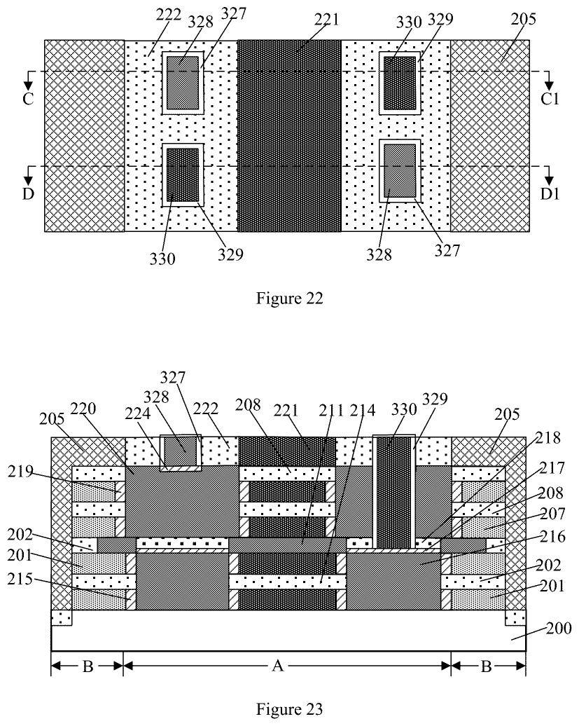

FIGS. 22 to 24 illustrate cross-sectional structural schematic diagrams corresponding to certain stages of another exemplary process of forming a semiconductor structure, consistent with the disclosed embodiments of the present disclosure.

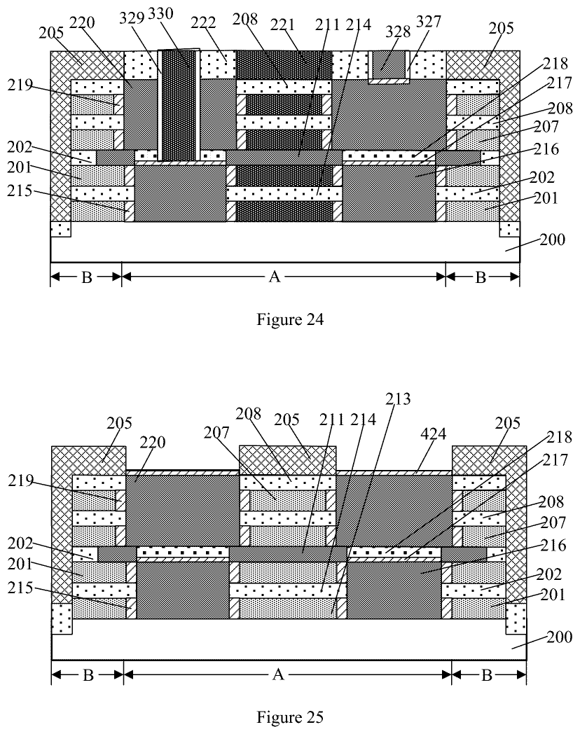

FIG. 22 is a top view of FIGS. 23 and 24. FIG. 23 is a schematic cross-sectional structural view of FIG. 22 along the section line CC1. FIG. 24 is a schematic cross-sectional structural diagram of FIG. 22 along the section line DD1 direction. Referring to FIGS. 22-24, in one embodiment, for the first connection layer 328 and the second connection layer 329 located on two sides of the gate structure 221, the central axis, parallel to the first direction, of the first connection layer 328 coincides with the central axis, parallel to the first direction, of the second connection layer 329.

That is, the first connection layers 330 on two sides of the gate structure 221 are located on a diagonal line, and the second connection layers 328 on two sides of the gate structure 221 are located on a diagonal line. The first connection layer 330 is electrically connected to the first doped source/drain region 216. The second connection layer 328 is electrically connected to the second doped source/drain region 220. Accordingly, circuit current taken out from the first connection layer 330 and circuit current taken out from the second connection layer 328 may have good uniformity.

FIG. 25 illustrates a cross-sectional structural schematic diagram corresponding to a certain stage of another exemplary process of forming a semiconductor structure, consistent with the disclosed embodiments of the present disclosure.

FIG. 25 is a schematic structural diagram based on FIG. 13. Referring to FIG. 25, a second metal layer (not shown) may be formed on the surface of the second doped source/drain region, and the second metal layer may be heat treated to form the second contact layer 424.

In one embodiment, the second contact layer 424 is located on the entire surface of the second doped source/drain region 220. As such, the overall area of the first contact layer 217 and the second contact layer 424 in the semiconductor structure may be increased. Since the first contact layer 217 and the second contact layer 424 are conductive, the resistance of the semiconductor structure may be reduced.

Reference may be made to FIGS. 14-21 for a subsequent process of forming the first connection layer and the second connection layer. Detail of the process will not be elaborated here.

The above description of the disclosed embodiments is provided to enable any person skilled in the art to make or use the present application. Various modifications to these embodiments will be readily apparent to those skilled in the art, and the general principles defined herein may be implemented in other embodiments without departing from the spirit or scope of the present disclosure. Therefore, the present disclosure will not be limited to the embodiments shown herein, but is to be accorded the broadest scope consistent with the principles and novel features disclosed herein.

1. A semiconductor structure, comprising:
a substrate;
a vertical stack structure located over the substrate, wherein the vertical stack structure includes a channel region and a source/drain region located on two sides of the channel region, an arrangement direction of the channel region and the source/drain region is perpendicular to an extension direction of the vertical stack structure, the channel region includes a first stack region, an isolation region located over the first stack region, and a second stack region located over the isolation region, the first stack region includes a plurality of first channel layers vertically stacked, a first groove is located between adjacent first channel layers of the plurality of first channel layers and between a first channel layer of the plurality of first channel layers and the isolation region, the second stack region includes a plurality of second channel layers that are discrete, and a second groove is located between adjacent second channel layers of the plurality of second channel layers and between a second channel layer of the plurality of second channel layers and the isolation region;
a first isolation layer located in the isolation region;
a gate structure over the substrate, wherein the gate structure surrounds the first channel layer and the second channel layer, and the gate structure is also located in the first groove and the second groove;
a first spacer located on a sidewall of the gate structure in the first groove, wherein the first spacer is located between the adjacent first channel layers and between the first channel layer and the first isolation layer, and the first spacer is flush with a sidewall of the first channel layer;
a second spacer located on a sidewall of the gate structure in the second groove, wherein the second spacer is located between the adjacent second channel layers and between the second channel layer and the first isolation layer, and the second spacer is flush with a sidewall of the second channel layer;
a first doped source/drain region located in the source/drain region on two sides of the first stack region;
a first contact layer located on a surface of the first doped source/drain region, wherein the first contact layer has a first projection on a surface of the substrate;
a second doped source/drain region located over the first contact layer, wherein the second doped source/drain region is located in the source/drain region on two sides of the second stack region;
a second contact layer located on a surface of the second doped source/drain region, wherein the second contact layer has a second projection on the surface of the substrate, and an area of the first projection is greater than or equal to an area of the second projection;
a second connection layer located on two sides of the gate structure, wherein the second connection layer is electrically connected to the second doped source/drain region through the second contact layer; and
a first connection layer located in the second doped source/drain region on two sides of the gate structure, wherein the first connection layer is electrically connected to the first doped source/drain region through the first contact layer.

2. The semiconductor structure according to claim 1, wherein:
the semiconductor structure includes a plurality of the vertical stack structures, and the plurality of the vertical stack structures is parallel to a first direction and arranged along a second direction, wherein the first direction and the second direction are parallel to the substrate surface, and the first direction is perpendicular to the second direction, and the gate structure spans a plurality of the channel regions, and the gate structure is parallel to the second direction.

3. The semiconductor structure according to claim 1, further comprising:
a second isolation layer located between the first contact layer and the second doped source/drain region, wherein a top surface of the second isolation layer is lower than or flush with a top surface of the first isolation layer; and/or
a first insulation layer located on a sidewall surface of the first connection layer, and a second insulation layer located on a sidewall surface of the second connection layer.

4. (canceled)

5. The semiconductor structure according to claim 1, wherein:
for the first connection layer and the second connection layer located on a same side of the gate structure, a central axis, parallel to an extension direction of the gate structure, of the first connection layer coincides with a central axis, parallel to the extension direction of the gate structure, of the second connection layer; and
central axes, parallel to the first direction, of the first connection layers located on two sides of the gate structure coincide, and the central axes, parallel to a first direction, of the second connection layers located on two sides of the gate structure coincide; or, for the first connection layer and the second connection layer located on two sides of the gate structure, the central axis, parallel to the first direction, of the first connection layer coincides with the central axis, parallel to the first direction, of the second connection layer.

6. (canceled)

7. The semiconductor structure according to claim 1, wherein:
a conductivity type of the first channel layer is N-type, and a conductivity type of the second channel layer is P type; or, the conductivity type of the first channel layer is P type, and the conductivity type of the second channel layer is N type.

8. A method of forming a semiconductor structure, comprising:
providing a substrate;
forming a vertical stack structure located over the substrate, wherein the vertical stack structure includes a channel region and a source/drain region located on two sides of the channel region, an arrangement direction of the channel region and the source/drain region is perpendicular to an extension direction of the vertical stack structure, the channel region includes a first stack region located over the substrate, an isolation region located over the first stack region, and a second stack region located over the isolation region, the first stack region includes a plurality of first channel layers that are discrete, a first groove is located between adjacent first channel layers of the plurality of first channel layers and between a first channel layer of the plurality of first channel layers and the isolation region, the second stack region includes a plurality of second channel layers that are discrete, and a second groove is located between adjacent second channel layers of the plurality of second channel layers and between a second channel layer of the plurality of second channel layers and the isolation region;
forming a first isolation layer located in the isolation region;
forming a gate structure over the substrate, wherein the gate structure surrounds the first channel layer and the second channel layer, and the gate structure is also located in the first groove and the second groove;
forming a first doped source/drain region in the source/drain region on two sides of the first stack region;
forming a first contact layer on a surface of the first doped source/drain region, wherein the first contact layer has a first projection on a surface of the substrate;
forming a second doped source/drain region over the first contact layer, wherein the second source/drain doping region is located in the source/drain region on two sides of the second stack region;
forming a second contact layer on part or entire of a surface of the second doped source/drain region, wherein the second contact layer has a second projection on the surface of the substrate, and an area of the first projection is greater than or equal to an area of the second projection;
forming a first connection layer in the second doped source/drain regions on two sides of the gate structure, wherein the first connection layer is electrically connected to the first doped source/drain region through the first contact layer; and
forming a second connection layer on two sides of the gate structure, wherein the second connection layer is electrically connected to the second doped source/drain region through the second contact layer.

9. The method according to claim 8, wherein a process of forming the vertical stack structure, the first isolation layer and the first doped source/drain region includes:
forming a first composite material layer over the substrate, wherein the first composite material layer includes a plurality of first stack structures, and a first stacked structure of the plurality of first stack structures includes an initial first sacrificial layer and an initial first channel layer located on the initial first sacrificial layer; forming a second composite material layer over the first composite material layer, wherein the second composite material layer includes a plurality of second stack structures, and a second stacked structure of the plurality of second stack structures includes an initial second sacrificial layer and an initial second channel layer located over the initial second sacrificial layer; forming a dummy gate structure over the substrate, wherein the dummy gate structure spans the first composite material layer and the second composite material layer; removing part of the second composite material layer on two sides of the dummy gate structure until a surface of the initial first channel layer of the first composite material layer is exposed, and forming a first opening in the second composite material layer, such that the initial second sacrificial layer is formed into a second sacrificial layer, the initial second channel layer is formed into a second channel layer, and a second stack area is formed; removing a portion of the initial first channel layer exposed by the first opening, and forming a second opening at a bottom of the first opening, wherein the second opening is also located at a bottom of the second sacrificial layer, and the isolation region is formed; forming the first isolation layer in the second opening at the bottom of the second sacrificial layer; after forming the first isolation layer, removing the first composite material layer exposed by the second opening until the surface of the substrate is exposed, and forming a third opening in the first composite material layer, such that the initial first sacrificial layer is formed into a first sacrificial layer, the initial first channel layer is formed into a first channel layer, and the first stack region is formed; and forming the first doped source/drain region in the third opening.

10. The method according to claim 9, wherein a process of forming the first contact layer includes:
forming a first metal layer on the surface of the first doped source/drain region; and
performing heat treatment on the first metal layer to form the first contact layer on the surface of the first doped source/drain region.

11. The method according to claim 9, before removing the portion of the initial first channel layer exposed by the first opening, further comprising:
forming an initial second spacer on a sidewall of the second sacrificial layer, wherein part of the initial second spacer is located between the second channel layers that are adjacent, and part of the initial second spacer is located on a sidewall of the second channel layer.

12. The method according to claim 11, after forming the first contact layer on the surface of the first doped source/drain region, further comprising:
forming a second isolation layer over the first contact layer, wherein a top surface of the second isolation layer is lower than or flush with a top surface of the first isolation layer.

13. The method according to claim 12, after forming the second isolation layer, further comprising:
removing the initial second spacer located on the sidewall of the second channel layer, and forming a second spacer on the sidewall of the second sacrificial layer, wherein the second spacer is located between the second channel layers that are adjacent, and the second spacer is flush with the sidewall of the second channel layer.

14. The method according to claim 13, wherein:
a process of forming the second doped source/drain region includes: after forming the second spacer, forming the second doped source/drain region in the first opening; and
a process of forming the vertical stack structure and the gate structure includes: after forming the second doped source/drain region, forming a dielectric structure over the substrate, wherein the dummy gate structure is located in the dielectric structure; removing the dummy gate structure, and forming a gate opening in the dielectric structure, wherein the gate opening exposes the second sacrificial layer, the second channel layer, the first sacrificial layer and a sidewall surface of the first channel layer; removing the second sacrificial layer and the first sacrificial layer exposed by the gate opening, and forming a first groove between the first channel layers that are adjacent and between the first channel layer and the first isolation layer, forming a second groove between the second channel layers that are adjacent and between the second channel layer and the first isolation layer, and thus forming the vertical stack structure;
and forming the gate structure in the gate opening, the first groove and the second groove.

15. (canceled)

16. The method according to claim 15, wherein a process of forming the first connection layer, the second connection layer and the second contact layer includes:
forming a third groove in the dielectric structure on two sides of the gate structure, wherein the third groove exposes part of the surface of the second doped source/drain region;
forming the second contact layer on the surface of the second doped source/drain region exposed by the third groove; after the second contact layer is formed, forming a filling layer in the third groove; after the filling layer is formed, forming a fourth groove in the dielectric structure on two sides of the gate structure and in the second doped source/drain region, wherein the fourth groove exposes part of a surface of the first contact layer; removing the filling layer, and forming an insulation layer on a sidewall of the third groove and a sidewall of the fourth groove; and after forming the insulation layer, forming the second connection layer in the third groove, and forming the first connection layer in the fourth groove.

17. The method according to claim 14, wherein:
a process of forming the second contact layer includes: forming a second metal layer on the surface of the second doped source/drain region, and performing heat treatment on the second metal layer to form the second contact layer; and
a process of forming the gate structure includes: after forming the second contact layer, forming a dielectric structure over the substrate, wherein the dummy gate structure is located in the dielectric structure; removing the dummy gate structure, and forming the gate structure in the dielectric structure.

18. (canceled)

19. The method according to claim 18, wherein a process of forming the first connection layer and the second connection layer includes:
forming a third groove in the dielectric structure on two sides of the gate structure, wherein the third groove exposes part of a surface of the second contact layer; forming a fourth groove in the dielectric structure on two sides of the gate structure and in the second doped source/drain region, wherein the fourth groove exposes part of a surface of the first contact layer; forming a second insulation layer on a sidewall of the third groove, and forming a first insulation layer on a sidewall of the fourth groove; and after forming the second insulation layer and the first insulation layer, forming the second connection layer in the third groove, and forming the first connection layer in the fourth groove.

20. The method according to claim 9, wherein:
the semiconductor structure includes a plurality of the first composite material layers, wherein the plurality of the first composite material layers is parallel to a first direction and arranged along a second direction, the first direction and the second direction are parallel to the surface of the substrate, and the first direction is perpendicular to the second direction; the semiconductor structure includes a plurality of the second composite material layers, wherein each of the second composite material layers is located over the first composite material layers; the dummy gate structure spans the first composite material layers and the second composite material layers, and the dummy gate structure is parallel to the second direction.

21. The method according to claim 9, wherein:
for the first connection layer and the second connection layer located on a same side of the gate structure, a central axis, parallel to an extension direction of the gate structure, of the first connection layer coincides with a central axis, parallel to the extension direction of the gate structure, of the second connection layer; and
central axes, parallel to a first direction, of the first connection layers located on two sides of the gate structure coincide, and central axes, parallel to the first direction, of the second connection layers located on two sides of the gate structure coincide; or, for the first connection layer and the second connection layer located on two sides of the gate structure, the central axis, parallel to the first direction, of the first connection layer coincides with the central axis, parallel to the first direction, of the second connection layer.

22. (canceled)

23. The method according to claim 9, before forming the first doped first doped source/drain region in the third opening, further comprising:
forming a first spacer on a sidewall of the first sacrificial layer, wherein the first spacer is located between the first channel layers that are adjacent, and the first spacer is flush with a sidewall of the first channel layer.

24. The method according to claim 23, wherein a process of forming the first spacer includes:
forming an initial first spacer on a sidewall of the first sacrificial layer, wherein part of the initial first spacer is located between the first channel layers that are adjacent, and part of the initial first spacers is located on the sidewall of the first channel layer; and removing the initial first spacer on the sidewall of the first channel layer, and forming the first spacer on the sidewall of the first sacrificial layer, wherein the first spacer is located between the first channel layers that are adjacent, and the first spacer is flush with the sidewall of the first channel layer.

25. The method according to claim 16, wherein a process of forming the second contact layer includes:
forming a second metal layer on the surface of the second doped source/drain region, and performing heat treatment on the second metal layer to form the second contact layer.
